(19) United States
(12) Patent Application Publication
(10) Pub. No.: US 2025/0160053 A1
(43) Pub. Date: May 15, 2025

(54) PRODUCTION METHOD, OPTOELECTRONIC SEMICONDUCTOR COMPONENT, AND CARRIER

(71) Applicant: ams-OSRAM International GmbH, Regensburg (DE)

(72) Inventors: Thomas Schwarz, Regensburg (DE); Andreas Waldschik, Wolmirstedt (DE)

(21) Appl. No.: 18/838,175

(22) PCT Filed: Feb. 15, 2023
(86) PCT No.: PCT/EP2023/053736

§ 371 Date: Aug. 13, 2024

(30) Foreign Application Priority Data
Feb. 17, 2022 (DE) 10 2022 103 762.2
Apr. 26, 2022 (DE) 10 2022 110031.6

(51) Int. Cl. H10H 20/01; H10H 20/857

(52) U.S. Cl. CPC H10H 20/0364; H10H 20/857

(57) ABSTRACT

In an embodiment a method includes providing a circuit board having a first main side and a second main side as well as metallic electrical contact structures located on the first main side, applying electrical compensation structures to the first main side directly on at least some of the contact structures, the compensation structures projecting beyond the respective one of the contact structures in the direction parallel to the first main side, wherein a distance between adjacent compensation structures assigned to one another is at most 50 μm and is smaller than a distance between adjacent contact structures assigned to one another, and applying at least one optoelectronic semiconductor chip directly to the compensation structures assigned to one another, wherein the contact structures and the assigned at least one semiconductor chip do not overlap when viewed from above on the first main side.

### CROSS-REFERENCE TO RELATED APPLICATIONS

This patent application is a national phase filing under section 371 of PCT/EP2023/053736, filed Feb. 15, 2023, which claims the priority of German patent application 102022103762.2, filed Feb. 17, 2022 and claims the priority of German patent application 102022110031.6, filed Apr. 26, 2022, each of which are incorporated herein by reference in its entirety.

### TECHNICAL FIELD

A method for manufacturing a semiconductor device is provided. In addition, an optoelectronic semiconductor device and a carrier for such an optoelectronic semiconductor device are also provided.

### SUMMARY

Embodiments provide an optoelectronic semiconductor device that can be manufactured efficiently.

According to at least one embodiment, the method comprises the step of providing a circuit board. The circuit board comprises, for example, a base body and at least one metallic electrical contact structure. The contact structure comprises, for example, a side of an electrical via and/or electrical conductive paths. In particular, the contact structure comprises one or more of the following metals or consists of one or more of these metals: Ag, Al, Au, Cu, Ni, Sn, Pd. For example, the contact structure is made of copper or a copper alloy. It is possible that the contact structure is of multilayer-fashion or consists of only a single metal layer.

According to at least one embodiment, the circuit board has a first main side and a second main side. The main sides are opposite each other. It is possible that one of the main sides or both main sides are flat. The first main side is intended for mounting at least one semiconductor chip. The second main side is configured for mounting the semiconductor device on an external carrier, such as a circuit arrangement. The second main side can be configured for surface mount technology, or SMT for short, of the semiconductor device.

According to at least one embodiment, the method comprises the step of applying at least one electrical compensation structure. The compensation structure or structures are applied to the first main side indirectly or directly to at least some of the contact structures, for example, by sintering or baking or soldering or adhesion.

For example, there is an unambiguous or one-to-one assignment between the compensation structures and the contact structures. This means that each of the contact structures provided for a semiconductor chip can be electrically connected to one or more of the compensation structures.

Furthermore, it is possible that the compensation structures and/or the contact structures are arranged in pairs and/or assigned to each other. For example, two of the compensation structures are each combined in a pair and these two compensation structures are provided for a single semiconductor chip. Accordingly, a pair of the contact structures can be present so that these two contact structures are assigned to the respective pair of compensation structures.

According to at least one embodiment, the compensation structures project beyond the relevant contact structures in a direction parallel to the first main side. In particular, the contact structures of a pair run towards each other, starting from the assigned contact structures.

According to at least one embodiment, a distance between neighboring, mutually associated compensation structures is smaller than a distance between neighboring, mutually associated contact structures. This means that the compensation structures can be used to create finer and/or smaller electrical structures than is possible with the contact structures alone. In particular, there are smaller position tolerances when manufacturing the compensation structures than when manufacturing the contact structures.

For example, the distance between the adjacent compensation structures assigned to each other is at most 50 μm or at most 20 μm or at most 15 μm or at most 10 μm or at most 6 μm. This makes it possible, for example, to attach small light-emitting diode chips, or LEDs for short, to the compensation structures.

In at least one embodiment, the method is used to manufacture a semiconductor device and comprises the following steps, in particular in the order given:
A) providing a circuit board having a first main side and a second main side as well as metallic electrical contact structures on the first main side,
B) applying electrical compensation structures to the first main side, in particular directly to at least some of the contact structures, the compensation structures projecting beyond the relevant contact structures in a direction parallel to the first main side,
wherein a distance between adjacent compensation structures assigned to one another being at most 20 μm and being smaller than a distance between adjacent contact structures assigned to one another. Optionally, the method further comprises:
C) applying at least one semiconductor chip directly to the mutually associated compensation structures, wherein the contact structures and the associated at least one semiconductor chip do not overlap as seen in plan view of the first main side.

With the method described herein, a more cost-effective, simple structure for enabling the smallest pad spacing for the assembly of components with the smallest P-N spacing can be realized. A material used for this purpose, in particular for the compensation structures, can also provide an interconnect function. The term ‘pad’ refers in particular to an electrical connection surface that is configured for the attachment of a semiconductor chip.

Semiconductor devices produced using this method can be used, for example, in the automotive sector, in consumer electronics or for interior lighting.

For the assembly of μLEDs, that is, light-emitting diode chips with areas of less than 0.1 mm×0.1 mm, for example, substrates with pad-to-pad distances of up to 10 μm are required. There are only a few substrate technology approaches that can in principle meet these requirements, such as printed circuit boards with embedded tracks, ETS-PCB for short, printed circuit boards with electroplated tracks, SAT-PCB for short or Semi Additive Technology-PCB, or thin film circuit films, such as Ajinomoto Build-up Films, ABF for short. However, such substrates are comparatively expensive or have technical disadvantages:
the contact pads are a few micrometers below a substrate surface due to the manufacturing process and/or the structure spacing is subject to relatively large tolerances of +/−5 μm, for example;
the interconnect material for μLED contacting must be applied to these available substrates in an additional process step during the further manufacturing process, which results in additional costs and tolerances.

In substrate production, attempts are made in particular to reduce the line width and spacing of the pads further and further. There are prepreg-based and ABF-based methods, where prepreg stands for pre-impregnated and means that an only partially cured, fiber-reinforced material is used to structure conductive paths. Other approaches include the direct lithographic structuring of silver pastes, which is expensive, or the laser-assisted transfer of interconnect material. However, the latter requires fine structures on the circuit board to which the material can be applied. At the same time, printing processes can be optimized to such an extent that structure distances down to 15 μm can be achieved.

The method and semiconductor device described herein are based in particular on the idea that a very simply constructed, roughly structured basic substrate is combined as a circuit board with, for example, a cost-effective printing process that enables the desired structure spacing. There is no need to apply an additional interconnect material, as the printed material can function both as a conductor track or redistribution structures and as an interconnect into which the component is inserted and contacted by heating.

In the method described herein, circuit boards, also referred to as substrates, are used in particular, which only have a coarse structuring, which have no or hardly any topography, that is, height differences, on a μLED mounting side. This enables cost-efficient printing with particularly fine screen meshes, also referred to as fine screen mesh-micro gap. This allows very small pad-to-pad distances to be realized. In addition, the resolution can be further improved by using lithographically structurable pastes, for example a Raybrid material. Due to the combined use of these methods in particular, the substrate does not need to have a metallization directly under the semiconductor chip-an overlap between the printed material, that is, the compensation structure, and the substrate metallization, that is, the contact structure, is therefore located outside a particularly critical component area where fine structuring is required.

This means that coarser or specially designed structures can be provided in non-critical areas to compensate for possible tolerances during printing. The printed material, that is, the compensation structure, can simultaneously serve as a conductor track and interconnect material.

With the method described herein, it is therefore possible to use cost-effective substrates with comparatively large tolerances. The assembly of components, such as horizontal μLEDs with pad-to-pad distances of 15 μm or less, is made possible by the finely printed structures, that is, the compensation structure. No additional material needs to be applied for the interconnect-this shortens the tolerance chain itself by one step, as the conductor track and interconnect material can be applied in a single process step. By applying a finely structured layer to the coarsely structured substrate, alignment tolerances and height tolerances can also be compensated for at the same time. In the case of substrates with vias, the space required for a via cap can be dispensed with, thereby reducing the component size and/or making better use of the top of the component and enabling printing on a flat substrate.

According to at least one embodiment, the method further comprises a step C): C) applying at least one semiconductor chip, in particular an optoelectronic semiconductor chip, to the mutually associated compensation structures. For example, the semiconductor chip or each of the semiconductor chips or some of the semiconductor chips are each applied to two of the compensation structures. This means that the at least one semiconductor chip is electrically contacted by means of the compensation structures. The at least one semiconductor chip can be applied directly to the associated compensation structures or there is merely a connecting means, such as a solder or an electrically conductive adhesion, between the at least one semiconductor chip and the associated compensation structures.

In addition to the at least one optoelectronic semiconductor chip, at least one further semiconductor chip can be installed, for example, a control chip such as an IC chip. It is possible for the additional semiconductor chip to be contacted electrically and mechanically in the same way as the at least one optoelectronic semiconductor chip.

According to at least one embodiment, several of the semiconductor chips are applied per semiconductor device. For example, at least three or at least ten or at least 10² or at least 10³ or at least 10⁴ of the semiconductor chips are present per semiconductor device. Alternatively or additionally, this number is at most 10⁷ or at most 10⁶ or at most 10⁵ or at most 10⁴ or at most 10³.

According to at least one embodiment, the at least one optoelectronic semiconductor chip is configured to generate light, in particular visible light. Different types of semiconductor chips can be combined with each other in one semiconductor device, for example, red, green and blue emitting semiconductor chips and/or white and red emitting semiconductor chips and/or semiconductor chips with white emission of different correlated color temperatures.

According to at least one embodiment, the at least one semiconductor chip or all semiconductor chips or some of the semiconductor chips have a size of at most 0.3 mm×0.3 mm or of at most 0.1 mm×0.2 mm or of at most 0.1 mm×0.2 mm or of at most 40 μm×20 μm when viewed from above onto the first main side. This means that the semiconductor chips can be μLEDs.

It is possible for each or some of the semiconductor chips to have a single luminous area. Alternatively, the semiconductor chips or at least some of the semiconductor chips can have several light emitting areas, so that pixelated semiconductor chips can be present.

According to at least one embodiment, the semiconductor chip or chips each have chip contact surfaces on a mounting side facing the first main side. The at least one semiconductor chip can therefore be a flip chip. The chip contact surfaces are attached to the associated compensation structures. For example, the distance between the chip contact surfaces is at most 20 μm or at most 10 μm.

According to at least one embodiment, the compensation structures are only hardened after the semiconductor chips have been applied. This means, for example, that the semiconductor chips are fixed to the circuit board by curing the compensation structures. The compensation structures can thus serve as an interconnect, that is, as connecting means, between the circuit board and the semiconductor chips.

According to at least one embodiment, step A) comprises the following substeps, in particular in the order given:
A1) providing the circuit board comprising electrical vias from the first main side to the second main side and/or at least one through-hole metallization on the first main side and/or on the second main side, and
A2) structuring the at least one through-hole metallization so that electrical connection surfaces result on the second main side.

According to at least one embodiment, step A) further comprises the following sub-step, which can be carried out, for example, within step A2):
A3) complete removal of the metallization on the first main side, wherein in particular at least some of the vias on the first main side are exposed and these exposed vias form the contact structures. Accordingly, in step A1), in particular a circuit board with one of the metallizations on each of the first and second main sides was previously provided.

According to at least one embodiment, step B) comprises the following sub-step:
B1) generating electrical compensation tracks, which are part of the compensation structures, starting from the exposed vias.

It is therefore possible for the compensation structures to form conductor tracks, in particular starting from the via or starting from a metallization directly at the vias.

According to at least one embodiment, the exposed vias form the contact structures. In other words, the contact structures may consist of the exposed vias. In particular, the exposed vias are then not provided with a metallization extending to the first main side.

According to at least one embodiment, the circuit board comprises one or more embedded conductor tracks on the first main side, which are electrically connected to the vias and which form the contact structures, optionally together with a partial region of the relevant vias. Embedded means, for example, that the conductor tracks are flush with the base body of the circuit board and thus run along the first main side and/or that the conductor tracks run at least partially within the base body and thus at least in places below the first main side.

According to at least one embodiment, a planarization layer is applied between adjacent vias, in particular those associated with a particular semiconductor chip. The planarization layer can completely cover an area of the first main side that lies between the relevant vias. For example, the planarization layer is flush with a metallization on the relevant vias in the direction away from the first main side.

According to at least one embodiment, the compensation structures are partially or completely generated on the planarization layer. Starting from the relevant vias or the metallization on the relevant vias, the compensation structures of a pair then extend towards each other, for example, as conductor tracks.

According to at least one embodiment, the circuit board is translucent, in particular for visible light. For example, the circuit board is clear or milky opaque. This applies in particular to the base body of the circuit board. The base body is then made of a translucent plastic or glass, for example.

According to at least one embodiment, at least some of the contact structures are configured as conductor tracks,
whereby the compensation structures can originate from the conductor tracks that are covered by the contact structure.

According to at least one embodiment, step B) comprises the following sub-steps, in particular in the order indicated:
B2) applying a layer of raw material,
B3) exposing the raw material layer, and
B4) removing excess material from the raw material layer so that the compensation structures result.

In other words, the compensation structures can be generated photolithographically.

According to at least one embodiment, step B) comprises the following sub-step:
B5) generating the compensation structures by means of screen printing and/or by means of stencil printing.

According to at least one embodiment, a plurality of pairs are generated from the compensation structures and, in particular, one pair of associated contact structures per pair of these compensation structures. The following applies, for example, individually or in combination:
The distance between the neighboring, mutually assigned contact structures is greater than or equal to the distance between the neighboring, mutually assigned compensation structures plus a position tolerance of the compensation structures relative to the assigned contact structures, and/or
the distance between the neighboring, mutually assigned compensation structures is greater than or equal to an assembly tolerance for semiconductor chips plus a manufacturing tolerance of chip contact surfaces.

The position tolerance and the assembly tolerance as well as the manufacturing tolerance can be determined, for example, by a statistical analysis of one or more of the semiconductor devices manufactured, especially if many of the semiconductor chips are installed per semiconductor device.

According to at least one embodiment, the contact structures form a cross-shaped pattern and/or a star-shaped pattern and/or a T-shaped pattern in places or as a whole when viewed in plan view of the first main side. It is possible that the compensation structures partially or completely overlap with the pattern.

According to at least one embodiment, the compensation structures or some of the compensation structures each comprise one or any combination of two or all of the following elements:
a connection region configured for attachment of the semiconductor chips,
an elongation extending away from the connection region and being narrower than or as wide as the associated connection region when viewed in plan view of the first major side, and
one or more extensions that run transversely to the elongation and extend beyond the elongation and are distant from the connection region.

According to at least one embodiment, a width of the elongation is greater than the distance between the neighboring, mutually assigned compensation structures. This means that a factor delimiting the geometric precision of the compensation structures and thus of electrical contacting is in particular the distance between the compensation structures in question and not their width.

According to at least one embodiment, a width of the connection region exceeds the width of the elongation by at least a factor of 1.5 or by at least a factor of 2 or by at least a factor of 3. Alternatively or additionally, this factor is at most 10 or at most 6 or at most 3.

According to at least one embodiment, a length of the at least one extension, in the direction transverse to the associated elongation, exceeds the width of this elongation by at least a factor of 1.5 or by at least a factor of 2 or by at least a factor of 3. Alternatively or additionally, this factor is at most 10 or at most 6 or at most 3.

According to at least one embodiment, the compensation structures are made of a sintering paste and/or a photosensitive paste and/or an adhesive paste. Alternatively or additionally, the compensation structures comprise one or more of the following materials or consist of one or more of these materials: Ag, Au, Cu, Ni, carbon. In the case of carbon, the compensation structures may comprise or consist of one or more of the following forms of carbon: carbon black, carbon nanotubes, soot, graphite.

According to at least one embodiment, the contact structures are generated by etching and/or electroplating.

Further provided is an optoelectronic semiconductor device. In particular, the optoelectronic semiconductor device is produced by a method as described in connection with one or more of the above embodiments. Features of the optoelectronic semiconductor device are therefore also disclosed for the method and vice versa.

In at least one embodiment, the optoelectronic semiconductor device comprises:
a circuit board having a first main side and a second main side and metallic electrical contact structures on the first main side,
electrical compensation structures on the first main side, in particular directly on at least some of the contact structures, so that the compensation structures project beyond the relevant contact structures in a direction parallel to the first main side, and
optoelectronic semiconductor chips on the compensation structures assigned to one another,
wherein preferably furthermore individually or in any combination:
the optoelectronic semiconductor chips are configured to generate light and have a size of at most 0.1 mm×0.2 mm when viewed from above on the first main side,
the optoelectronic semiconductor chips each have chip contact surfaces on a mounting side facing the first main side and the chip contact surfaces are attached to the associated compensation structures, and
a distance between adjacent compensation structures assigned to one another is at most 15 μm and is smaller than a distance between adjacent contact structures assigned to one another.

In addition, a carrier for an optoelectronic semiconductor device is provided. In particular, the carrier is provided for a method as described in connection with one or more of the above embodiments. Features of the carrier are therefore also disclosed for the method as well as for the optoelectronic semiconductor device, and vice versa.

In at least one embodiment, the carrier is provided for an optoelectronic semiconductor device and comprises:
a circuit board having a first main side and a second main side and metallic electrical contact structures on the first main side, and
electrical compensation structures on the first main side directly on at least some of the contact structures, such that the compensation structures project beyond the respective contact structures in a direction parallel to the first main side,
the electrical compensation structures being configured for attaching semiconductor chips, in particular optoelectronic semiconductor chips.

According to at least one embodiment, some or all of the optoelectronic semiconductor chips are micro-LEDs. For example, a micro-LED is any light-emitting diode, or LED for short, and in particular not a laser, with a particularly small size. It is possible for micro-LEDs to have a growth substrate removed, so that a height of such micro-LEDs is in the range of 1.5 μm to 10 μm, for example. Such micro-LEDs can be provided on wafers with non-destructively detachable holding structures for the micro-LED.

In principle, a micro-LED does not necessarily have to have a rectangular radiation emitting surface. For example, a micro-LED can have a radiation emitting surface that is smaller than or equal to 100 μm or smaller than or equal to 70 μm in any lateral extension of the radiation emitting surface when viewed from above the micro-LED. For example, in the case of rectangular micro-LEDs, an edge length, particularly when viewed from above, is less than or equal to 70 μm or less than or equal to 50 μm.

Micro-LEDs are currently primarily used in displays. The micro-LEDs form pixels or sub-pixels and emit light of a defined color. Due to the small pixel size and high density with a small distance, micro-LEDs are suitable for small monolithic displays for applications in the field of augmented reality, AR, in particular for data glasses. Other applications are also being worked on, in particular in data communication or pixelated lighting applications. Various spellings for micro-LEDs can be found in the literature, such as μLED, μ-LED, uLED, u-LED or Micro Light Emitting Diode.

### BRIEF DESCRIPTION OF THE DRAWINGS

In the following, an optoelectronic semiconductor device described herein, a carrier described herein and a method described herein are explained in more detail with reference to the drawing by means of exemplary embodiments. Identical reference signs indicate same elements in the individual figures. However, no references to scale are shown; rather, individual elements may be shown in exaggerated size for better understanding.

FIG. 1 is a schematic sectional view of an exemplary embodiment of an optoelectronic semiconductor device described here;

FIG. 2 is a schematic top view of the optoelectronic semiconductor device of FIG. 1;

FIGS. 3 to 8 are schematic sectional views of steps of an exemplary embodiment of a manufacturing process for optoelectronic semiconductor devices described herein;

FIG. 9 is a schematic sectional view of an exemplary embodiment of an optoelectronic semiconductor device described here;

FIGS. 10 to 12 are schematic sectional views of steps of an exemplary embodiment of a manufacturing process for optoelectronic semiconductor devices described herein;

FIGS. 13 to 15 are schematic sectional views of steps of an exemplary embodiment of a manufacturing process for optoelectronic semiconductor devices described herein;

FIGS. 16 to 18 are schematic sectional views of steps of an exemplary embodiment of a manufacturing process for optoelectronic semiconductor devices described herein;

FIGS. 19 to 21 are schematic top views of steps of an exemplary embodiment of a manufacturing process for optoelectronic semiconductor devices described herein;

FIGS. 22 to 25, 27 and 29 are schematic top views of exemplary embodiments of carriers for optoelectronic semiconductor devices described herein;

FIGS. 26 and 28 are schematic top views of exemplary embodiments of circuit boards for optoelectronic semiconductor devices described herein; and

FIGS. 30 and 31 are schematic sectional views of exemplary embodiments of optoelectronic semiconductor devices described herein.

### DETAILED DESCRIPTION OF ILLUSTRATIVE EMBODIMENTS

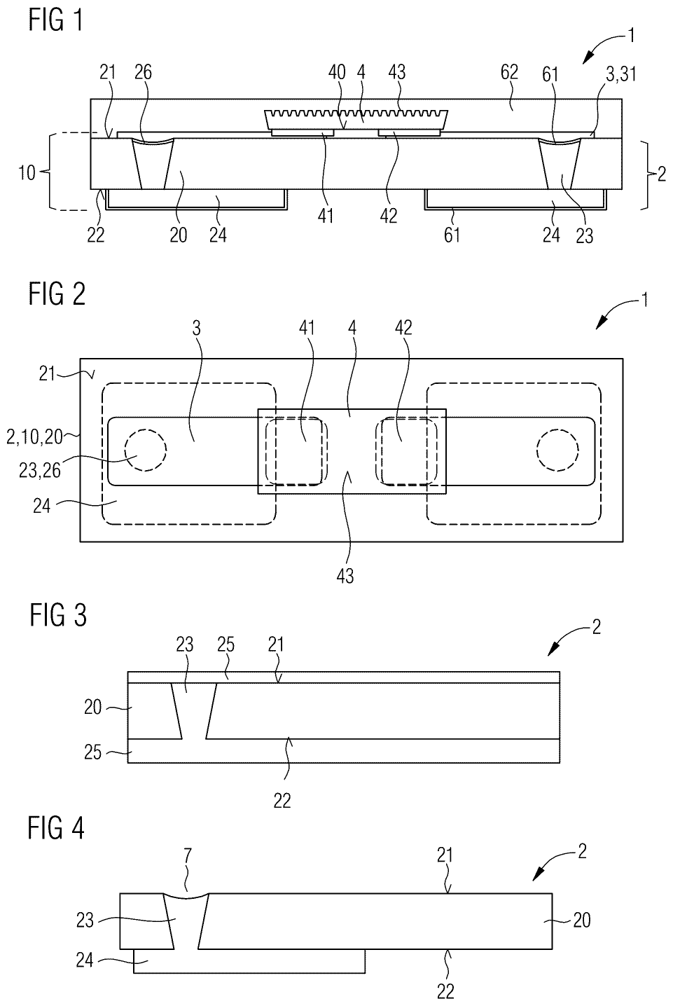

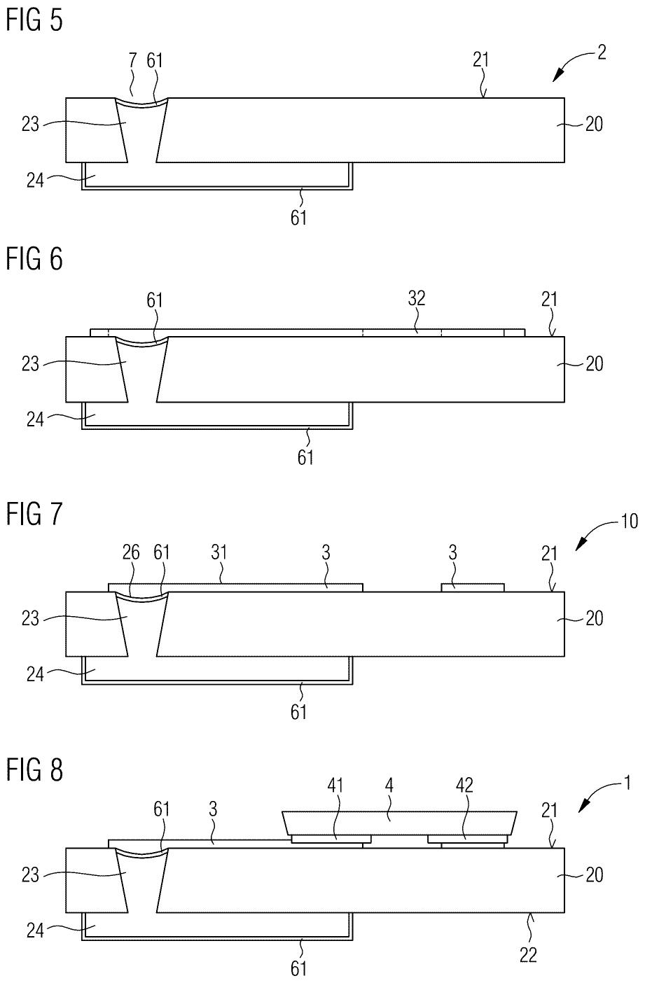

FIGS. 1 and 2 show an example of an optoelectronic semiconductor device 1. The semiconductor device 1 comprises a circuit board 2. The circuit board 2 comprises a base body 20, which is made of an opaque circuit board material such as FR-4. Alternatively, the base body 20 can also be made of a ceramic, for example AlN, or of a semiconductor material such as silicon.

Vias 23 are formed in the base body 20. The vias 23 can taper in the direction towards a first main side 21. For example, the vias 23 are partially or completely filled with a metal. Furthermore, the circuit board 2 includes a plurality of electrical connection surfaces 24 on a second main side 22, which are configured for surface mounting of the semiconductor device 1.

Optionally, there is a coating 61 on the connection surfaces 24 and/or on an exposed area of the via 23 on the first main side 21, which is in particular made of one or more metals. The coating 61 is, for example, a metal layer applied without external current, also referred to as an electro-less plating layer.

The via 23 and the connection surfaces 24 can be produced with comparatively large tolerances and thus cost-efficiently. This is made possible in particular by the use of electrical compensation structures 3. The compensation structures 3 are attached to the first main side 21 and include compensation tracks 31, which are configured as conductor paths and extend from the vias 23 to a semiconductor chip 4, such as a μLED. The compensation structures 3 can be manufactured with smaller tolerances than the electrical structures of the circuit board 2. The circuit board 2 together with the compensation structures 3 forms a carrier 10.

The semiconductor chip 4 is mounted on the two compensation tracks 31 of the compensation structures 3, a first chip contact surface 41 and a second chip contact surface 42 being located on a mounting side 40 of the semiconductor chip 4. The mounting side 40 faces the first main side 21. An emission side 43 is facing away from the carrier 10. A distance between the chip contact surfaces 41, 42 is, for example, 0.01 mm.

FIGS. 1 and 2 show only one semiconductor chip 4 and the two associated compensation tracks 31 and vias 23. Preferably, the semiconductor device 1 has a plurality of semiconductor chips 4 which are electrically contacted in the same way as the semiconductor chip 4 drawn.

Furthermore, a protective body 62 made of a translucent material is optionally provided. The protective body 62 can be flush with the carrier 10 and can completely cover the semiconductor chip 4. Optionally, the protective body 62 comprises a phosphor, not shown. Such a protective body 62 may also be present in all other examples.

This means that the semiconductor chip 4 as shown in FIGS. 1 and 2 can be applied directly to the precisely manufacturable compensation structure 3, so that no further connecting means, also known as an interconnect, is required. Since only the compensation structures 3 have to be manufactured with low manufacturing tolerances, but not the circuit board 2, the carrier 10 is comparatively inexpensive to manufacture overall.

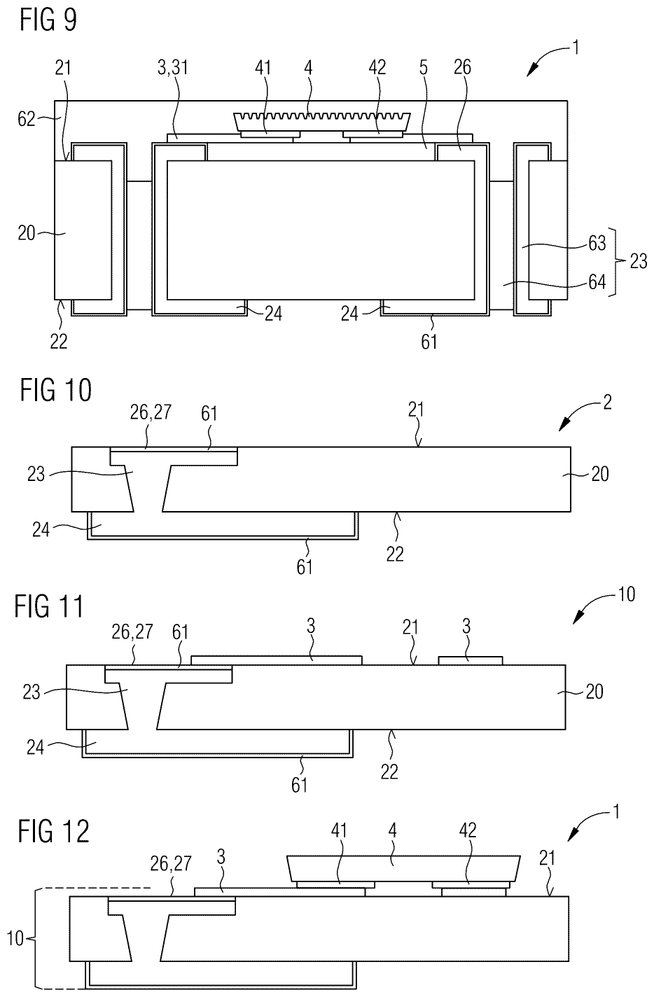

FIGS. 3 to 8 illustrate a manufacturing process for a semiconductor device 1, as shown in conjunction with FIGS. 1 and 2. According to FIG. 3, a circuit board 2 is provided. The circuit board 2 comprises vias 23, wherein only one of the vias 23 is drawn to simplify the illustration, the corresponding applies to all other vias 23; this also applies to the further examples. There is a metallization 25 on both the first main side 21 and the second main side 22 of the base body 20. The metallizations 25 completely cover the main sides 21, 22 and thus also the via 23.

In the step shown in FIG. 4, the metallization 25 on the first main side 21 has been completely removed so that the via 23 is exposed. This can result in a recess 7 on the first main side 21. A depth of the recess 7 is, for example, at most 40% or at most 20% of a diameter of the via 23 on the first main side 21. On the second main side 22, the connection surfaces 24 are structured from the metallization there.

In the step shown in FIG. 5, the coating 61 is applied to the exposed metal surfaces of the via 23 and the connection surfaces 24.

According to FIG. 6, a raw material layer 32 is applied. The raw material layer 32 is structured, for example, by photo-technical means. The raw material layer 32 is, for example, a Raybrid paste from the manufacturer TORAY INDUSTRIES, INC. Thus, the raw material layer 32 can be made of a photosensitive silver paste. A high manufacturing accuracy can be achieved by photo-structuring. Alternatively or in addition to a photo technique, a screen printing process or a stencil printing process can also be used to generate the compensation structure 3.

After structuring, see FIG. 7, excess material of the raw material layer 32 is removed, resulting in the compensation tracks 31 of the compensation structure 3. The material of the compensation structure 3 is not yet baked.

In the step shown in FIG. 8, the semiconductor chips 4, of which only one is shown, are applied to the compensation structure 3. The compensation structure 3 is then baked so that the semiconductor chips 4 are mechanically and electrically connected to the compensation structure 3 at the same time.

In all other respects, the comments on FIGS. 1 and 2 apply in the same way to FIGS. 3 to 8, and vice versa.

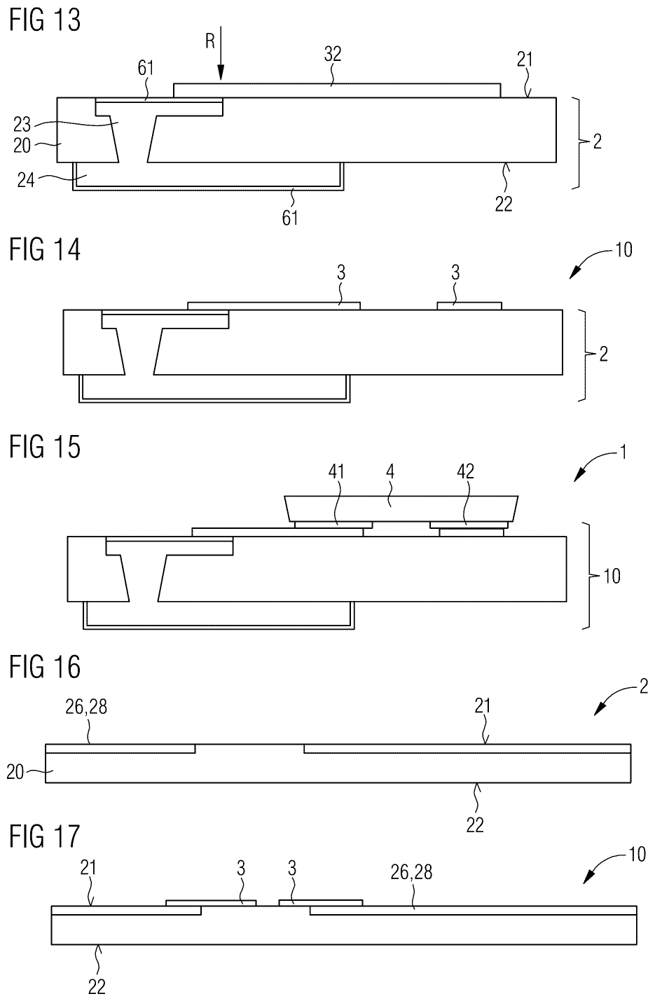

FIG. 9 illustrates another example of the semiconductor device 1. The vias 23 are formed by holes through the base body 20, which are provided on the inside with a metal layer 63. In particular, the metal layer 63 is formed integrally and continuously with the connection surfaces 24 and the contact structure 26. The connection surfaces 24 and the contact structure 26 thus extend from the metal layer 63 and can surround the respectively associated via 23 all around, as seen in plan view of the main side 21, 22 in question.

Optionally, the connection surfaces 24, the contact structure 26 and the metal layer 63 are covered by the coating 61. Furthermore, the via 23 is optionally sealed with a filling 64. The filling 64 is made of an epoxy, for example. It is possible that the filling 64 does not extend as far as the main sides 21, 22.

A planarization layer 5 made of a dielectric material, for example a plastic, is located between the areas of the contact structure 26 on the via 23. On a side facing away from the first main side 21, the contact structure 26 forms a common plane with the planarization layer 5. The compensation structure 3 is applied to this plane. The compensation structure 3 partially extends onto the contact structure 26. A distance between the contact structure 26 and the semiconductor chip 4 is bridged by the compensation structure 3 on the planarization layer 5.

Thus, the contact structure 26 and the semiconductor chip 4 do not overlap, as seen in plan view of the first main side 21. This can also apply in all other examples of the semiconductor device 1.

In all other respects, the comments on FIGS. 1 to 8 apply in the same way to FIG. 9, and vice versa.

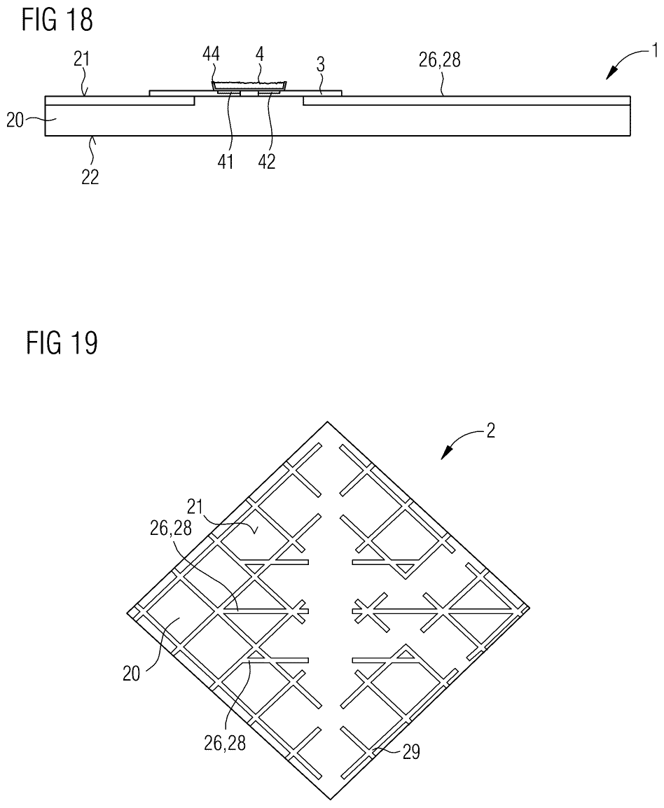

In the method of FIGS. 10 to 12, a printed circuit board with embedded traces, also referred to as ETS-PCB, is used as circuit board 2. According to FIG. 10, the connection surfaces 24 and embedded conductor tracks 27 of the contact structure 26 are already structured and the optional coating 61 is applied. The embedded conductor tracks 27 each extend from the assigned via 23. In FIGS. 10 to 15, the vias 23 widen in the direction towards the first main side 21, but it is equally possible for the vias 23 to become narrower towards the first main side 21, in contrast to what is shown in FIGS. 10 to 15. The second-mentioned variant can apply in particular in all ETS-PCB-based examples.

For example, the embedded conductor tracks 27 are not covered by a material of the base body 20 and extend at or near the first main side 21. It is possible that the embedded conductor tracks 27 are set back relative to the first main side 21, for example by at most 5 μm or by at most 2 μm, or that the embedded conductor tracks 27, together with the optional coating 61, are flush with the first main side 21, for example with a tolerance of at most 1 μm.

According to FIG. 11, the compensation structure 3 is generated, for example from a silver paste. This is done, for example, by screen printing or stencil printing, so that in particular no excess material for the compensation structure 3 is applied to the first main side 21 and so that no lithography process is necessary. A distance between the areas of the compensation structure 3 can be smaller than a width of the compensation structure 3, seen in plan view, not shown in FIG. 11.

The compensation structure 3 extends in part onto the embedded conductor tracks 27. Due to the embedded conductor tracks 27, the distance to be bridged by the precisely applied compensation structure 3 from the associated via 23 can be reduced, so that a reduction in line resistance can be achieved.

Furthermore, the compensation structure 3 can be used to compensate for a typical height tolerance of the substrate metallization, that is, the embedded conductor tracks 27.

Finally, according to FIG. 12, the at least one semiconductor chip 4 is applied, with baking of the compensation structure 3 taking place only after the semiconductor chip 4 has been applied, analogous to the process step of FIG. 8.

In all other respects, the explanations relating to FIGS. 1 to 9 apply in the same way to FIGS. 10 to 12, and vice versa.

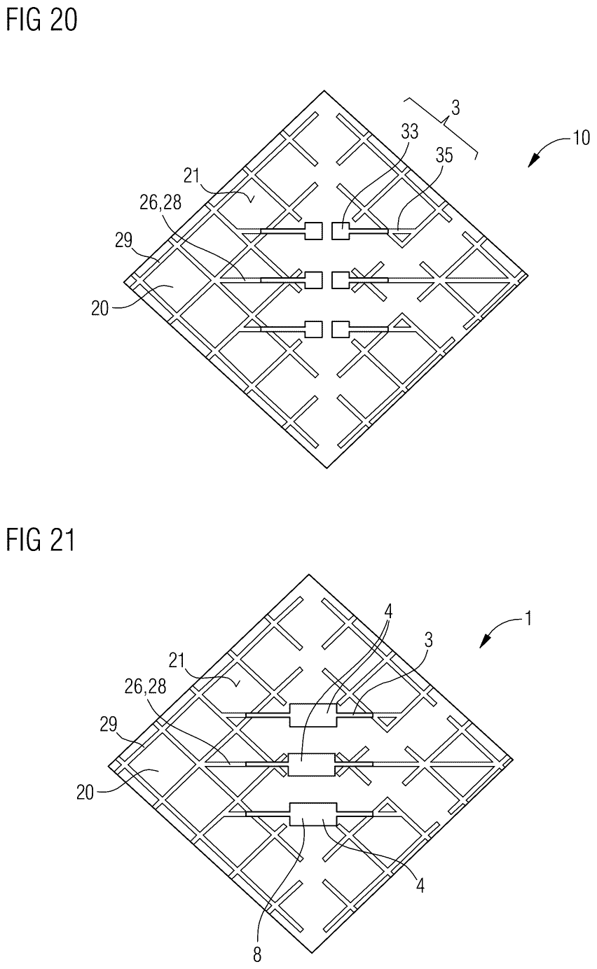

In the method of FIGS. 13 to 15, an ETS-PCB is also used as circuit board 2. According to FIG. 13, the raw material layer 32 is applied. The raw material layer 32 is then exposed to radiation R.

Subsequently, excess material of the raw material layer 32 is removed so that the compensation structure 3 is formed, see FIG. 14.

Finally, the at least one semiconductor chip 4 is attached, for example, analogous to the process steps of FIG. 8 or 12.

In all other respects, the explanations relating to FIGS. 1 to 12 apply in the same way to FIGS. 13 to 15, and vice versa.

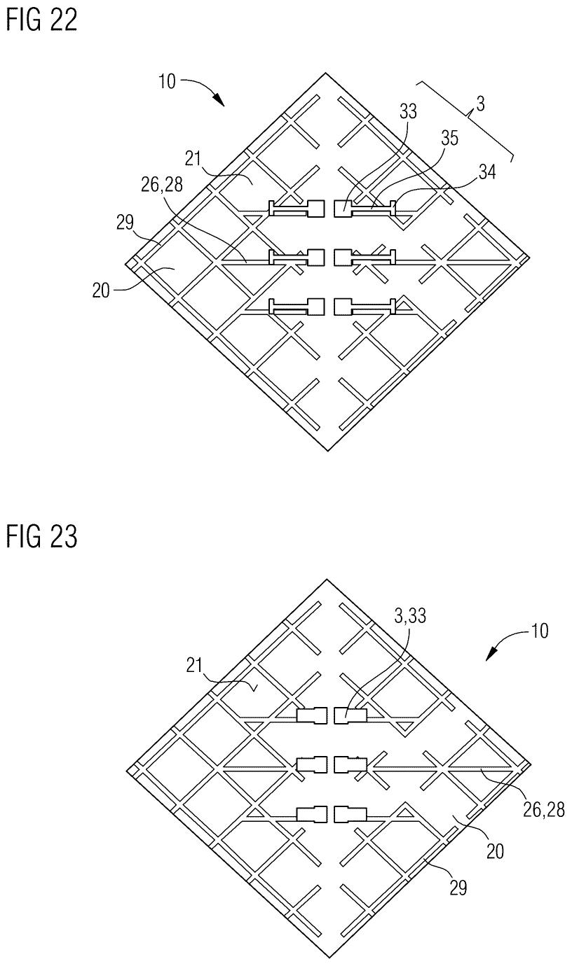

FIGS. 16 to 18 show another example of the method. According to FIG. 16, the circuit board 2 is provided. The circuit board 2 is an essentially transparent body. For example, the base body 20 is made of a translucent plastic. In particular, the base body 20 is a film, such as a polyethylene terephthalate film, or PET film for short. The contact structure 26 is located on the base body 20 and comprises, in particular, overlying conductor tracks 28. The conductor tracks 28 are made of copper or a copper alloy, for example, and can be produced by galvanization. As an alternative to overlying conductive tracks 28, embedded conductor tracks can also be used, analogous to FIGS. 10 to 15.

According to FIG. 17, the compensation structure 3 is generated. This is done, for example, according to the process steps in FIG. 11 or FIGS. 13 and 14.

Subsequently, according to FIG. 18, the at least one semiconductor chip 4 is attached, for example according to the process steps of FIG. 8, 12 or 15.

In all other respects, the explanations relating to FIGS. 1 to 15 apply in the same way to FIGS. 16 to 18, and vice versa.

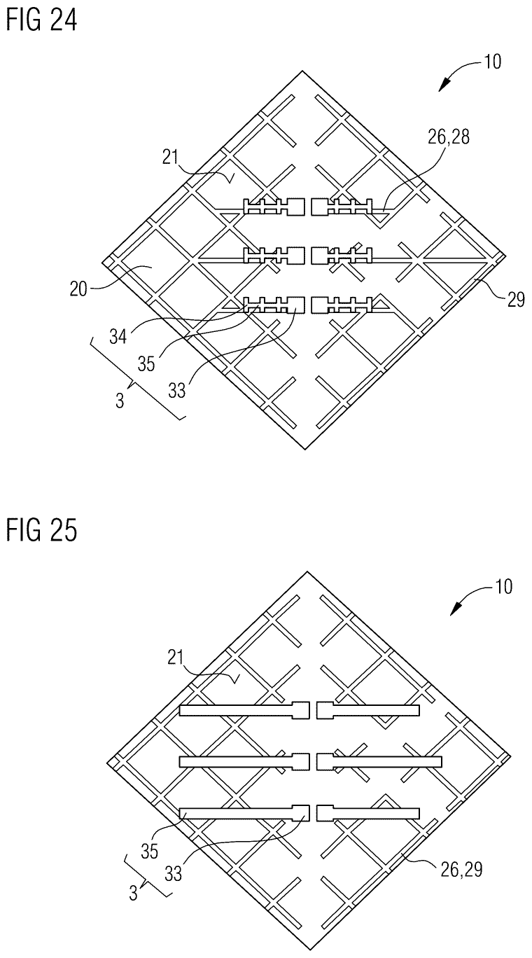

In the method of FIGS. 19 to 21, a transparent base body 20 is also used, but base bodies 20 made of ceramic or opaque plastic can also be used.

Referring to FIG. 19, the transparent circuit board 2 is provided. A cross-shaped, square pattern 29 is provided on the first main side 21. The pattern 29 is perforated, for example, along a first diagonal direction in order to ensure a distance between associated contact structures 26. In addition to the pattern 29, the contact structure 26 comprises the conductor tracks 28. The conductor tracks 28 run, for example, along a second diagonal direction, so that the conductor tracks 28 each cross the pattern 29 at one or more points. In this way, many connection points for the semiconductor chips 4 can be realized.

FIG. 20 shows the carrier 10 resulting from the circuit board 2 together with the compensation structures 3. The compensation structures 3 each comprise a connection region 33, which is later connected to one of the chip contact surfaces 41, 42. Furthermore, the compensation structures 3 each comprise an elongation 35, which extends from the associated connection regions 33. Due to the elongation 35, an exact positioning of the compensation structures 3 relative to the contact structure 26 is not mandatory, since there are in any case intersections with the pattern 29 and/or with the conductor tracks 28.

According to FIG. 21, the optoelectronic semiconductor chips 4 are then applied, which are, for example, red, green and blue emitting μLEDs.

Optionally, in addition to the optoelectronic semiconductor chips 4, a further semiconductor chip 8 is provided, which may, for example, be an IC chip for driving the optoelectronic semiconductor chips 4. The further semiconductor chip 8 can be contacted in the same way as the optoelectronic semiconductor chips 4. A conductor path diagram for the further semiconductor chip 8 is not drawn in detail in FIG. 21, but is merely illustrated in a highly simplified manner.

The semiconductor chips 4, 8 are applied, for example, in the same way as the methods described above.

The carriers 10 of the examples according to FIGS. 1 to 15 are based, for example, on opaque base bodies 20. Dimensions of these carriers 10, seen in plan view of the first main side 21, are, for example, at least 0.5 mm×0.5 mm and/or at most 5 mm×5 mm, typically 1 mm×0.5 mm. In contrast, the substantially transparent carriers 10 of FIGS. 16 to 21, for example designed as a film, can be significantly larger and have dimensions, seen in plan view of the first main side 21, of at least 5 cm×10 cm and/or of at most 1 m×2 m.

The smaller carriers 10 according to FIGS. 1 to 15 carry, for example, only one or more of the optoelectronic semiconductor chips 4, for example, at least three and/or at most 30 of the optoelectronic semiconductor chips 4. In contrast, the larger carriers 10 of FIGS. 16 to 21 can carry many of the optoelectronic semiconductor chips 4, for example, at least 100 and/or at most 10,000 of the optoelectronic semiconductor chips 4.

In all examples, it is possible that the associated compensation structures 3, in particular their connection regions 33, have a distance to one another of at least 5 μm and/or at most 20 um or at most 50 μm. A width of the compensation tracks 31 and/or the elongations 35 is, for example, at least 5 μm and/or at most 500 μm. A length of the compensation tracks 31 and/or the elongations 35 is, for example, at least 50 μm and/or at most 5 mm. A size of the connection regions 33 is based in particular on a size of the chip contact surfaces 41, 42 provided for this purpose. A thickness of the compensation structures 3 is, for example, at least 0.2 μm and/or at most 20 μm, in particular at least 1 μm and/or at most 3 μm. A thickness of the contact structures 26, 27, 28, 29 and/or the connection surfaces 24 is, for example, at least 1 μm and/or at most 40 μm. A width of the contact structures 26, 27, 28, 29 and/or the connection surfaces 24 is, for example, at least 5 μm and/or at most 100 μm, in particular at least 10 um and/or at most 20 μm. These aforementioned values can apply individually or in any combination.

In all other respects, the explanations relating to FIGS. 1 to 18 apply in the same way to FIGS. 19 to 21, and vice versa.

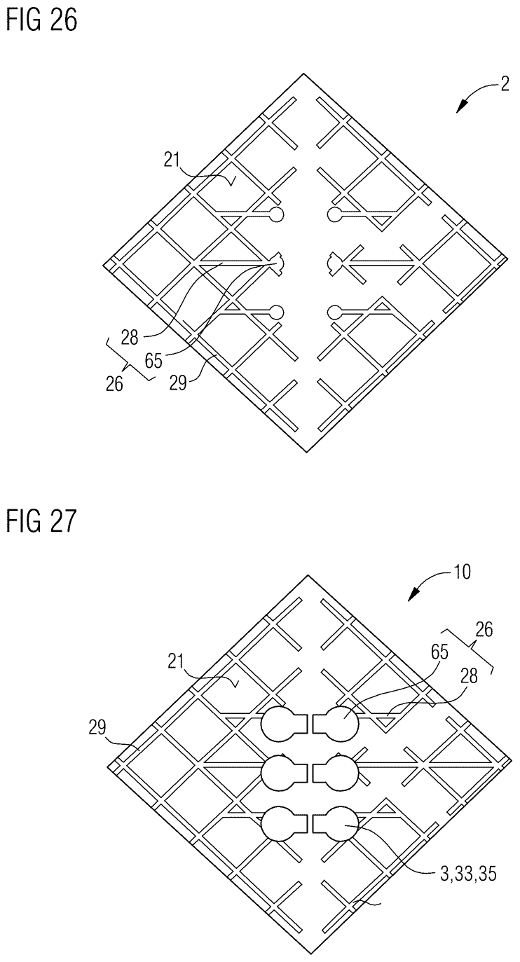

FIG. 22 shows that the compensation structures 3 each have an extension 34 at an end of the elongations 35 facing away from the connection regions 33. The extensions 34 run transversely, in particular perpendicularly, to the associated elongation 35. Seen from above, the compensation structures 3 can thus be bone-shaped. The extensions 34 provide an additional positioning tolerance of the compensation structures 3 with respect to the contact structures 26.

According to FIG. 23, the compensation structures 3 have comparatively wide elongations 35. A width of the elongations 35 is, for example, at least 50% and/or at most 150% or at most 95% of a width of the respective connection regions 33. The width refers in particular to an expansion perpendicular to the associated conductor tracks 28.

According to FIG. 24, several of the extensions 34 are present per elongation 35, for example at least two and/or at most six of the extensions 34, in order to ensure an increased positioning tolerance. Viewed from above, the compensation structures 3 can therefore be designed like a herringbone pattern.

According to FIG. 27, the compensation structures 3 are provided with rectangular connection regions 33 and round elongations 35. A diameter of the elongations 35 is, for example, larger than a diagonal length of the connection regions 33.

Furthermore, the compensation structures 3 can be provided with comparatively long elongations 35, see FIG. 25. A length of the elongations 35 exceeds the diagonal length of the connection regions 33, for example, by at least a factor of 3 and/or by at most a factor of 30.

FIG. 25 also shows that only the pattern 29 is present, so that the contact structures 26 are free of the conductor tracks 28. This is also possible in all other examples. The long elongations 35 nevertheless ensure a secure overlap with the associated contact structures 26.

The respective, differently designed compensation structures 3 of FIGS. 21 to 25 and 27 can be used accordingly in all examples. Thus, the explanations relating to FIGS. 1 to 21 apply in the same way to FIGS. 22 to 25 and 27, and vice versa.

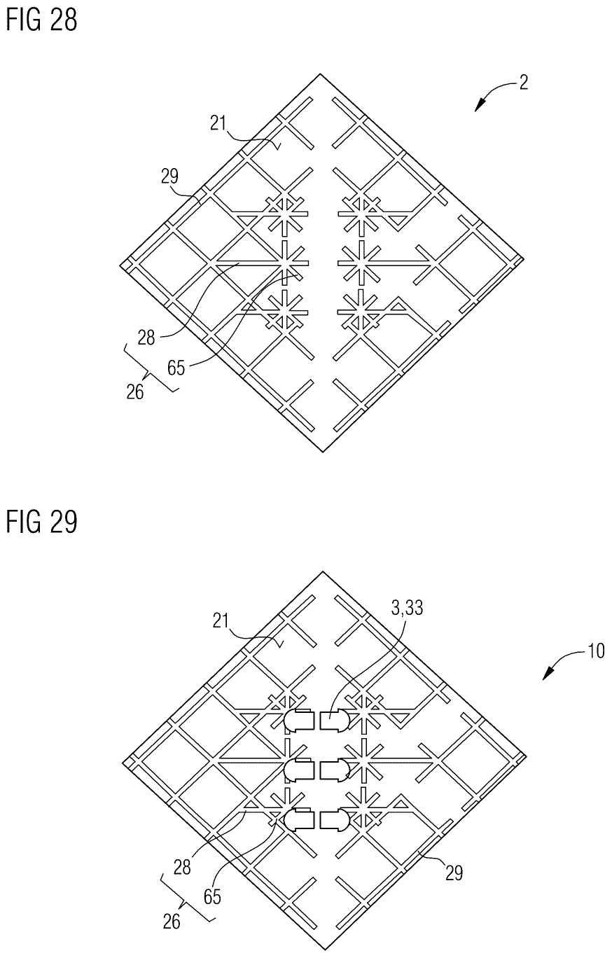

FIG. 26 shows that the contact structures 26 can each have contact point areas 65. The contact point areas 65 are, for example, round extensions of the pattern 29 and/or of the conductor tracks 28. The contact point areas 65 overlap with the elongations 35, whereby the connection regions 33 and the contact point areas 65 do not overlap, see FIG. 27. The contact point areas 65 are preferably smaller than the connection regions 33 in order to achieve a high transparency of the semiconductor device 1. Due to the contact point areas 65 in combination with the elongations 35, large positioning tolerances can be achieved.

FIG. 28 shows that the contact structures 26 are provided with star-shaped contact point areas 65 in order to achieve large positioning tolerances, see also FIG. 29. An expansion of the star-shaped contact point areas 65 is, for example, larger than the connection regions 33 together with the elongations 35 in order to ensure a high transparency of the carrier 10.

In all other respects, the explanations relating to FIGS. 1 to 25 apply in the same way to FIGS. 26 to 29, and vice versa.

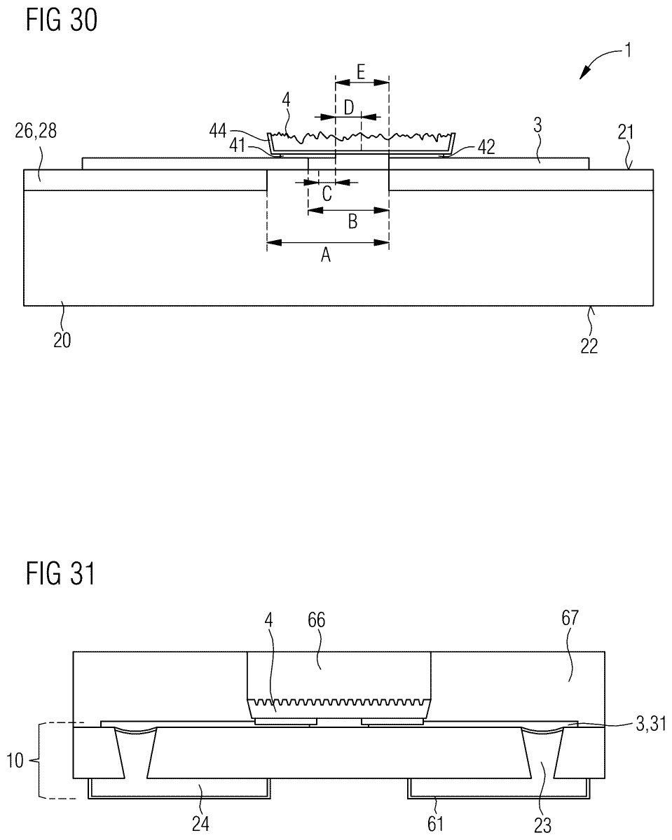

In the example of FIG. 30, the at least one optoelectronic semiconductor chip 4 is shown to have a trough-shaped reflector 44 that opens in a direction away from the first main side 21. Furthermore, dimensions are illustrated in FIG. 30.

A stands for the distance between neighboring contact structures 26, B stands for the distance between neighboring compensation structures 3, C is a position tolerance of the compensation structures 3 relative to the contact structures 26, D is an assembly tolerance of the semiconductor chips 4, 8 relative to the compensation structures 3 and E is a manufacturing tolerance of the chip contact surfaces 41, 42 with regard to a distance between the chip contact surfaces 41, 42. Tolerances in the process sequence arise specifically due to the positioning of the compensation structures 3 on the contact structures 26 and also due to the positioning of the semiconductor chips 4, 8 on the compensation structures 3.

For the aforementioned variables, the following applies in particular, individually or in any combination:

B≥E or B>E, in order to reduce the risk of electric shorts due to material migration,

B≥E+D or B>E+D,

and/or

A≥B+C or A>B+C.

In the example of FIG. 31, a luminescent body 66 is applied to the semiconductor chip 4. The luminescent body 66 may be produced directly on the semiconductor chip 4 or may be manufactured separately and then applied to the semiconductor chip 4. It is possible for the luminescent body 66 to be congruent with the semiconductor chip 4 within the manufacturing tolerances when viewed from above or to protrude laterally beyond the semiconductor chip 4, for example, by at most 10% of an edge length of the semiconductor chip 4.

As a further option, a reflector body 67 is provided. The reflector body 67 is, for example, made of a plastic, such as a silicone, which is filled with reflective particles, for example, of a metal oxide such as titanium dioxide. The reflector body 67 can be directly adjacent to a side surface of the semiconductor chip 4 and/or the luminescent body 66, in particular over the entire side surface. It is possible that the reflector body 67 has a lower average thickness than the luminescent body 66 and becomes thicker in the direction towards the luminescent body 66. The luminescent body 66 and the reflector body 67 may be flush with each other in the direction away from the first main side 21. It is possible that the reflector body 67 extends under the semiconductor chip 4, in particular into a region between the chip contact surfaces 41, 42.

Such a reflector body 67 and/or such a luminescent body 66 may also be present in all other embodiments.

In all other respects, the explanations relating to FIGS. 1 to 30 apply in the same way to FIG. 31, and vice versa.

The components shown in the figures preferably follow one another in the order indicated, in particular directly one after the other, unless otherwise described. Components not touching each other in the figures preferably have a distance between them. If lines are drawn parallel to each other, the associated surfaces are preferably also aligned parallel to each other. In addition, the relative positions of the drawn components to each other are shown correctly in the figures, unless otherwise specified.

The invention described herein is not limited by the description based on the embodiments. Rather, the invention includes any new feature as well as any combination of features, which includes in particular any combination of features in the patent claims, even if this feature or combination itself is not explicitly stated in the patent claims or embodiments.

1.-20. (canceled)

21. A method for manufacturing a semiconductor device, the method comprising:
providing a circuit board having a first main side and a second main side as well as metallic electrical contact structures located on the first main side;
applying electrical compensation structures to the first main side directly on at least some of the contact structures, the compensation structures projecting beyond the respective one of the contact structures in the direction parallel to the first main side,
wherein a distance between adjacent compensation structures assigned to one another is at most 50 μm and is smaller than a distance between adjacent contact structures assigned to one another; and
applying at least one optoelectronic semiconductor chip directly to the compensation structures assigned to one another,
wherein the contact structures and the assigned at least one semiconductor chip do not overlap when viewed from above on the first main side.

22. The method according to claim 21,
wherein the optoelectronic semiconductor chips are configured to generate light and have a size of at most 0.1 mm×0.2 mm when viewed from above onto the first main side,
wherein each of the optoelectronic semiconductor chips has a chip contact surface on a mounting side facing the first main side, and wherein the chip contact surfaces are attached to the associated compensation structures.

23. The method according to claim 22, wherein at least 3 and at most 10⁵ of the optoelectronic semiconductor chips are applied to the first main side of the semiconductor device.

24. The method according to claim 23, further comprising hardening
the compensation structures only after the optoelectronic semiconductor chips have been applied and fixing the optoelectronic semiconductor chips to the circuit board by the hardening of the compensation structures.

25. The method according to claim 21, wherein providing the circuit board comprises:
providing the circuit board comprising electrical vias extending from the first main side to the second main side and at least one continuous metallization located on the first main side and/or on the second main side, and
structuring the at least one continuous metallization so that electrical connection surfaces result on the second main side.

26. The method according to claim 25, wherein providing the circuit board further comprises:
completely removing the metallization on the first main side so that at least some of the vias on the first main side are exposed and form the contact structures,
wherein providing the circuit board comprises providing the circuit board with one of the metallizations on the first main side and on the second main side, and
wherein applying the electrical compensation structures comprises
generating electrical compensation tracks, which are part of the compensation structures, starting from the exposed vias.

27. The method according to claim 26,
wherein the exposed vias form the contact structures.

28. The method according to claim 25,
wherein the circuit board comprises conductor tracks embedded in the first main side, which are electrically connected to the vias and which form the contact structures.

29. The method according to claim 25, further comprising applying
a planarization layer between adjacent vias, wherein the compensation structures are partially formed on the planarization layer.

30. The method according to claim 21,
wherein the circuit board is translucent and on the first main side at least some of the contact structures are configured as conductor tracks, and
wherein the compensation structures extend starting from the conductor tracks.

31. The method according to claim 21,
wherein applying the electrical compensation structure comprises:
applying a raw material layer;
exposing the raw material layer; and
removing excess material from the raw material layer so that the compensation structures result.

32. The method according to claim 21,
wherein applying the electrical compensation structures comprises:
generating the compensation structures by screen printing or stencil printing.

33. The method according to claim 21,
wherein a plurality of pairs of the compensation structures and the contact structures assigned to these compensation structures is formed,
wherein the distance between the adjacent contact structures assigned to each other is greater than or equal to the distance between the adjacent compensation structures plus a position tolerance of the compensation structures relative to the assigned contact structures, and
wherein the distance between the adjacent, mutually associated compensation structures is greater than or equal to a mounting tolerance for the optoelectronic semiconductor chips plus a manufacturing tolerance of chip contact surfaces.

34. The method according to claim 21,
wherein the contact structures form at least partly a cross-shaped and/or star-shaped pattern as seen in plan view of the first main side, and wherein the compensation structures overlap with the pattern.

35. The method according to claim 21,
wherein each of the compensation structures comprises:
a connection region configured for an attachment of semiconductor chips,
an elongation, which extends away from the connection region and is narrower than the associated connection region as seen in plan view of the first main side, and
at least one extension, which extends transversely to the elongation and beyond the elongation and which is arranged distant from the connection region.

36. The method according to claim 35,
wherein
a width of the elongation is greater than the distance between the adjacent compensation structures assigned to one another,
wherein a width of the connection region exceeds the width of the elongation by at least a factor of 2,
wherein a length of the at least one extension, in a direction transverse to the elongation, exceeds the width of the elongation by at least a factor of 2.

37. The method according to claim 21,
wherein the compensation structures are made of a sintering paste and/or of a photosensitive paste and comprise Ag, Au, Cu, Ni and/or carbon, and
wherein the contact structures are produced by etching and/or electroplating.

38. An optoelectronic semiconductor device comprising:
a circuit board having a first main side, a second main side and metallic electrical contact structures located on the first main side;
electrical compensation structures located on the first main side directly on at least some of the contact structures so that the compensation structures project beyond the associated contact structures in a direction parallel to the first main side; and
optoelectronic semiconductor chips located on the mutually associated compensation structures,
wherein the optoelectronic semiconductor chips are configured to generate light and have a size of at most 0.1 mm×0.2 mm when viewed from above onto the first main side,
wherein each of-the optoelectronic semiconductor chips has a chip contact surface facing the first main side, wherein the chip contact surfaces are attached to the associated compensation structures, and
wherein a distance between adjacent, mutually associated compensation structures is at most 50 μm and is smaller than a distance between adjacent, mutually associated contact structures.

39. A carrier for producing optoelectronic semiconductor devices used in the method of claim 21, the carrier comprising:
the circuit board having the first main side and the second main side as well as the metal electrical contact structures located on the first main side; and
the electrical compensation structures located on the first main side directly on at least some of the contact structures so that the compensation structures project beyond the associated contact structures in the direction parallel to the first main side,
wherein the electrical compensation structures are configured for attaching optoelectronic semiconductor chips.

40. A method for manufacturing a semiconductor device, the method comprising:
providing a circuit board having a first main side and a second main side as well as metallic electrical contact structures located on the first main side;
applying electrical compensation structures to the first main side directly on at least some of the contact structures, the compensation structures projecting beyond the respective one of the contact structures in a direction parallel to the first main side,
wherein a distance between adjacent compensation structures assigned to one another is at most 50 μm and is smaller than a distance between adjacent contact structures assigned to one another;
applying at least one semiconductor chip directly to the compensation structures assigned to one another,
wherein the contact structures and the assigned at least one semiconductor chip do not overlap when viewed from above on the first main side,
wherein the optoelectronic semiconductor chips are configured to generate light and have a size of at most 0.1 mm×0.2 mm when viewed from above onto the first main side,
wherein each of the optoelectronic semiconductor chips has a chip contact surface on a mounting side facing the first main side, wherein the chip contact surfaces are attached to the associated compensation structures; and
hardening the compensation structures only after the optoelectronic semiconductor chips have been applied and fixing the optoelectronic semiconductor chips to the circuit board by hardening of the compensation structures.
